(19) United States
(12) Patent Application Publication
(10) Pub. No.: US 2025/0098143 A1
(43) Pub. Date: Mar. 20, 2025

(54) SEMICONDUCTOR MEMORY DEVICE

(71) Applicant: Kioxia Corporation, Tokyo (JP)

(72) Inventor: Ryota NARASAKI, Yokkaichi Mie (JP)

(21) Appl. No.: 18/882,640

(22) Filed: Sep. 11, 2024

(30) Foreign Application Priority Data
Sep. 15, 2023 (JP) 2023-150300

(51) Int. Cl. H10B 12/00

(52) U.S. Cl. CPC H10B 12/30; H10B 12/02

(57) ABSTRACT

According to an embodiment a semiconductor memory device includes a laminated structure with first layers and second layers alternately stacked in a first direction. A first and second bit line extends through the laminated structure. The second bit line is spaced from the first bit line in a second direction. Each first layer has a word line that extends in the second direction, a first semiconductor layer that extends alongside word line and is connected to the first bit line, a second semiconductor layer that extends alongside the word line and is spaced from the first semiconductor layer in the second direction, a gate insulating layer between the word line and the first or second semiconductor layer, a part of a first capacitor connected to the first semiconductor layer, and a part of a second capacitor connected to the second semiconductor layer.

### CROSS-REFERENCE TO RELATED APPLICATIONS

This application is based upon and claims the benefit of priority from Japanese Patent Application No. 2023-150300, filed Sep. 15, 2023, the entire contents of which are incorporated herein by reference.

### FIELD

Embodiments described herein relate generally to a semiconductor memory device.

### BACKGROUND

A semiconductor memory device that is a DRAM (dynamic random access memory) that is a three-dimensional structure integrated on a semiconductor substrate has been proposed.

### BRIEF DESCRIPTION OF THE DRAWINGS

FIG. 1 is a perspective view schematically illustrating a configuration of a semiconductor memory device according to an embodiment.

FIG. 2 is a cross-sectional view schematically illustrating the configuration of a semiconductor memory device according to an embodiment.

FIG. 3 is a cross-sectional view schematically illustrating the configuration of a semiconductor memory device according to an embodiment.

FIG. 4 is a perspective view schematically illustrating a part of the configuration of a semiconductor memory device according to an embodiment.

FIGS. 5A to 5J are perspective views schematically illustrating aspects of a manufacturing method of a semiconductor memory device according to an embodiment.

### DETAILED DESCRIPTION

A three-dimensional type semiconductor memory device capable of reducing a cell size is provided.

In general, according to one embodiment, a semiconductor memory device includes a laminated structure with a plurality of first layers and a plurality of second layers alternately stacked in a first direction. A first bit line extends in the first direction through the laminated structure. A second bit line that extends in the first direction through the laminated structure. The second bit line is spaced from the first bit line in a second direction crossing the first direction. Each first layer in the laminated structure includes: a word line that extends in the second direction, a first semiconductor layer that extends in the second direction alongside word line and is connected to the first bit line, a second semiconductor layer that extends in the second direction alongside the word line, the second semiconductor layer being spaced from the first semiconductor layer in the second direction and connected to the second bit line, a first gate insulating layer between the word line and the first semiconductor layer, a second gate insulating layer between the word line and the second semiconductor layer, a first part of a first capacitor connected to the first semiconductor layer, and a first part of a second capacitor connected to the second semiconductor layer.

Hereinafter, certain example embodiments will be described with reference to the drawings.

A semiconductor memory device according to the present embodiment is a DRAM having a three-dimensional structure. The semiconductor memory device has a structure in which a plurality of memory cells are three-dimensionally integrated in directions perpendicular and parallel to a main surface of a semiconductor substrate.

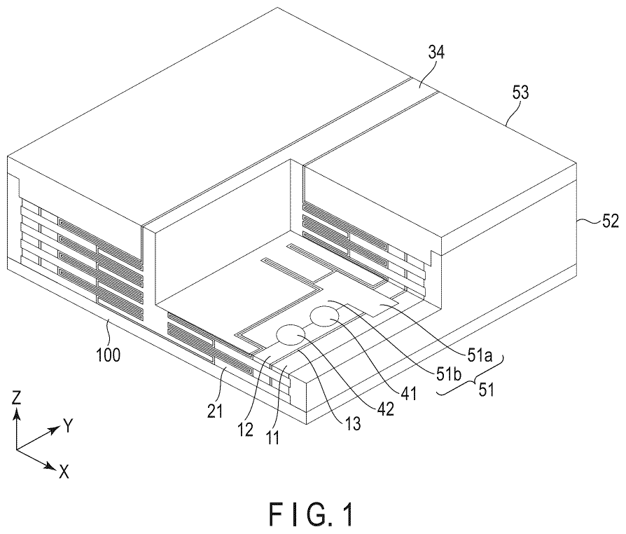

FIG. 1 is a perspective view schematically illustrating a configuration of the semiconductor memory device according to this embodiment. In FIG. 1, in one part on a front side of a quadrisected structure, a part on an upper layer side is omitted in order to make it easy to understand an internal structure, however, actually the part on the upper layer side also exists similarly to the other three parts.

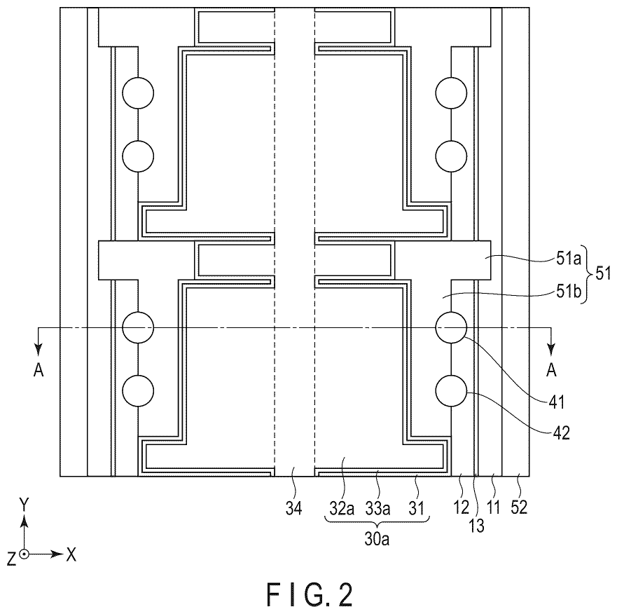

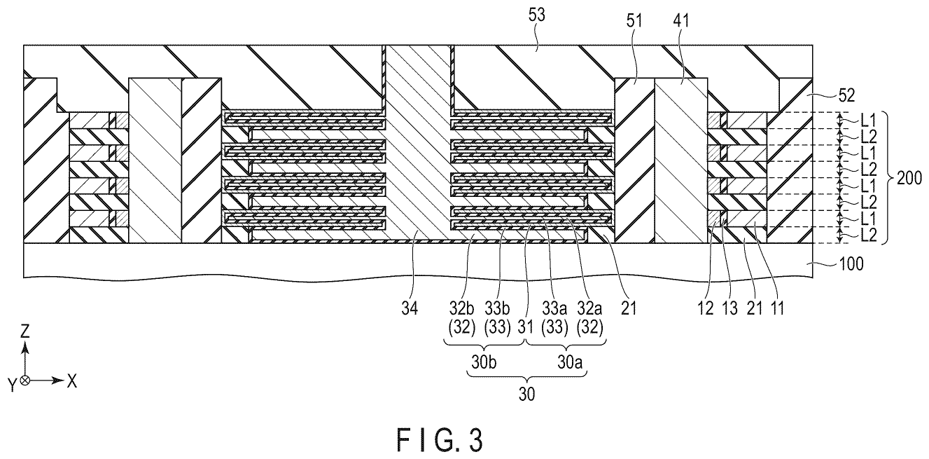

FIG. 2 is a cross-sectional view schematically illustrating the configuration of the semiconductor memory device according to this embodiment. FIG. 2 is view of a cut taken perpendicular to the Z direction. FIG. 3 is a cross-sectional view schematically illustrating the configuration of the semiconductor memory device according to the embodiment. FIG. 3 is a view of a cut taken parallel to the Z direction and corresponds to a cross section along an A-A line in FIG. 2.

In FIG. 1, FIG. 2, and FIG. 3, four laminate memory cell structures (also referred to as laminate memory cell blocks) having four memory cells laminated (stacked) in the Z direction are disposed in parallel with an XY plane (a plane perpendicular to the Z direction). That is, in FIG. 1, FIG. 2, and FIG. 3, four laminate memory cell blocks and sixteen (16) memory cells are illustrated. In general, in an actual device, a plurality of unit structures each including the four laminate memory cell blocks illustrated in FIG. 1, FIG. 2, and FIG. 3 would be arrayed in an X direction and a Y direction.

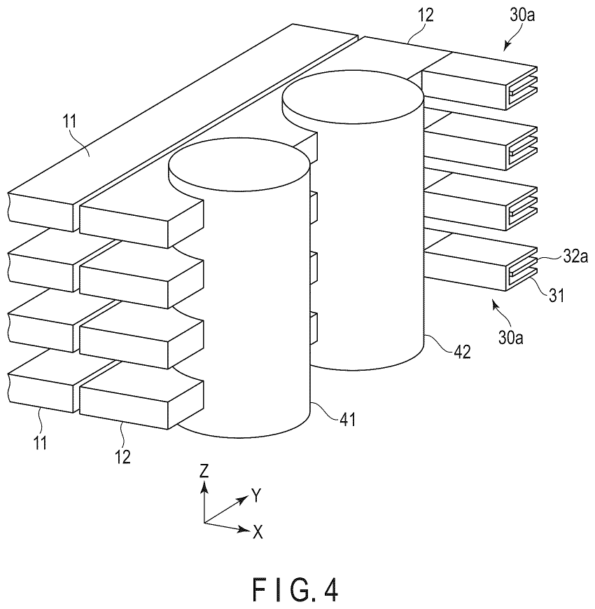

FIG. 4 is a perspective view schematically illustrating a part of the configuration illustrated in FIG. 1, FIG. 2, and FIG. 3. In FIG. 4, portions of an insulating material are omitted in order to make it easy to understand the other structure.

As illustrated in FIG. 1 to FIG. 4, on a semiconductor substrate 100 (silicon substrate), a laminate structure 200 with a plurality of first layers L1 and a plurality of second layers L2 alternately laminated in the Z direction is provided.

Each of the plurality of first layers L1 includes a word line 11 that extends in the Y direction, a semiconductor layer 12 that extends in the Y direction along the word line 11, a gate insulating layer 13 that is provided between the word line 11 and the semiconductor layer 12, and a first part 30a of a capacitor 30. That is, the laminated first layers L1 include the laminated word lines 11, the laminated semiconductor layers 12, the laminated gate insulating layers 13, and the laminated first parts 30a of the capacitors 30.

Each MOS transistor for the DRAM is formed by one word line 11, one semiconductor layer 12, and one gate insulating layer 13 provided in one first layer L1 in a laminate memory cell block. That is, the word line 11 functions as a gate electrode, and a channel is formed in the semiconductor layer 12. The word line 11 can be formed of a metal material such as tungsten (W), the semiconductor layer 12 can be formed of silicon, and the gate insulating layer 13 can be formed of silicon oxide.

Each of the capacitors 30 laminated in the Z direction is connected to a corresponding semiconductor layer 12 and functions as a capacitor for the DRAM.

When viewed from the Z direction, the laminated word lines 11 in the same laminate memory cell block overlap with each other, the laminated semiconductor layers 12 in the same laminate memory cell block overlap with each other, and the laminated gate insulating layers 13 in the same laminate memory cell block overlap with each other. In addition, when viewed from the Z direction, the laminated first parts 30a of the plurality of capacitors 30 in the same laminate memory cell block coincide in shape and position to each other. In the other laminate memory cell blocks, the patterns of the elements coincide in shape and position, though aspects may be mirrored in some instances.

When viewed from the Z direction, the laminated word lines 11 extend in the Y direction on the same straight line across laminate memory cell blocks arrayed in the Y direction. Similarly, laminated semiconductor layers 12 are aligned with each other along the Y-direction across laminate memory cell blocks arrayed in the Y direction, though the laminated semiconductor layers 12 may be divided into different sections at points along the Y-direction.

Each of the plurality of laminated second layers L2 includes an insulating layer 21 and a portion of a second part 30b of the capacitor 30. That is, the laminated second layers L2 include the laminated insulating layers 21 and a portion of the plurality of laminated second parts 30b of the plurality of capacitors 30. Each of the insulating layers 21 includes a part provided between word lines 11 adjacent to each other in the Z direction and a part provided between the semiconductor layers 12 adjacent to each other in the Z direction. The insulating layer 21 is formed of silicon oxide, for example.

When viewed from the Z direction, patterns of the plurality of laminated insulating layers 21 in each laminate memory cell block coincide with each other, and patterns of the plurality of laminated second parts 30b of the plurality of capacitors 30 in each laminate memory cell block coincide with each other.

Each capacitor 30 includes a capacitor electrode 31, a capacitor electrode 32, and a capacitor dielectric layer 33 provided between the capacitor electrode 31 and the capacitor electrode 32. The capacitor electrode 31 and the capacitor electrode 32 can be formed of a metal material such as tungsten (W), and the capacitor dielectric layer 33 can be formed of a dielectric material such as hafnium oxide (HfOₓ). Each capacitor electrode 31 is connected to a corresponding semiconductor layer 12. Each capacitor electrode 32 is connected to a common electrode 34.

Each capacitor 30 comprises a first part 30a and a second part 30b. The first part 30a is provided in the first layer L1 and includes a portion of capacitor electrode 31, a capacitor electrode 32a, and a capacitor dielectric layer 33a. The second part 30b includes a portion of capacitor electrode 31, a capacitor electrode 32b, and a capacitor dielectric layer 33b. That is, the second part 30b shares the capacitor electrode 31 provided in the first layer L1 and also includes parts (the capacitor electrode 32b and the capacitor dielectric layer 33b) provided in the second layer L2.

In the laminate structure 200, common electrode 34 extends in the Y direction and the Z direction. The common electrode 34 is provided between the laminate memory cell blocks adjacent to each other in the X direction. A plurality of capacitor electrodes 32 (the capacitor electrode 32a and the capacitor electrode 32b) laminated with each other in the Z direction are connected to the common electrode 34. The common electrode 34 can be formed of a metal material such as tungsten (W).

In addition, in the laminate structure 200, a plurality of bit lines 41 that extend in the Z direction, and a plurality of body contacts 42 that extend in the Z direction are provided. The plurality of bit lines 41 are separated from each other, and the plurality of body contacts 42 are also provided separated from each other. Each laminate memory cell block is provided with one bit line 41 and one body contact 42 that are separated from each other. The bit line 41 and the body contact 42 both have a columnar shape (see FIG. 4).

In each laminate memory cell block, the bit line 41 is connected to (in contact with) each of the laminated semiconductor layers 12, and the body contact 42 is also connected to (in contact with) each of the laminated semiconductor layers 12. The bit line 41 functions as a bit line for the DRAM, and a predetermined potential is supplied to the body contact 42.

The plurality of bit lines 41 and the plurality of body contacts 42 can be formed of the same conductive material (but need not be necessarily formed of the same material). In one example, the bit lines 41 and the body contacts 42 can be formed of a metal material such as tungsten (W).

In the laminate structure 200, an insulating part 51 that extends in the Z direction is provided. The insulating part 51 includes an insulating part 51a and an insulating part 51b that are integrally provided with each other. The insulating part 51a extends in the X direction and the Z direction in the laminate structure 200 and separates laminated semiconductor layers 23 into a first plurality of laminated semiconductor layer 12 and a second plurality of laminated semiconductor layers 12 that are adjacent to each other in the Y direction. The insulating part 51b extends in the Y direction and the Z direction in the laminate structure 200 and is adjacent to the plurality of laminated semiconductor layers 12 in the X direction. When viewed from the Z direction, the bit line 41 and the body contact 42 are positioned in a region between or at a boundary between the laminated semiconductor layers 12 and the insulating part 51b.

In the laminate structure 200, an insulating part 52 that extends in the Y direction and the Z direction is provided. The insulating part 52 is adjacent to the laminated word lines 11 in the X-direction, and extend along the Y-direction with laminated word lines 11 and are between laminate memory cell blocks that are adjacent to each other in the X direction.

The insulating part 51 (comprising the insulating part 51a and the insulating part 51b) and the insulating part 52 are formed of silicon oxide.

An upper insulating layer 53 can be provided on the laminate structure 200, the plurality of bit lines 41, the plurality of body contacts 42, the plurality of insulating parts 51, and the plurality of insulating parts 52. In some examples, the upper insulating layer 53 may not be provided. The upper insulating layer 53 can be formed of silicon nitride.

The semiconductor memory device according to the present embodiment is provided with a word line 11 and a semiconductor layer 12 in each of the plurality of first layers L1 laminated in the Z direction. By such a configuration, in the present embodiment, it is possible to reduce a cell size of a memory cell.

In the present embodiment, since both the word line 11 and the semiconductor layer 12 are provided in each first layer L1, it is possible to reduce a pitch in a perpendicular direction (Z direction) of the memory cells laminated in the perpendicular direction, and it is possible to reduce a device height in the perpendicular direction. If a word line and a semiconductor layer are provided in separate layers, since a layer for the word line and a separate layer for the semiconductor layer are needed, the overall device height in the perpendicular direction increases. In the present embodiment, since both the word line 11 and the semiconductor layer 12 are provided in a common layer (the same first layer L1), it is possible to reduce the size in the perpendicular direction.

In addition, in the present embodiment, since the semiconductor layer 12 is provided along the word line 11, it is possible to reduce a pitch in a horizontal direction (a direction parallel to the XY plane) of the memory cells arrayed in the horizontal direction, and it is possible to reduce device area required in the horizontal direction. When the semiconductor layer is not provided along the word line in the same layer and an extending direction of the word line and an extending direction of the semiconductor layer are different, a gate electrode part of the word line needs to be parallel to the semiconductor layer, and the gate electrode part needs to be branched from the word line itself. In the present embodiment, since the semiconductor layer 12 is provided along the word line 11 and the word line 11 and the semiconductor layer 12 extend in the same direction, it is possible to reduce the size required in the horizontal direction.

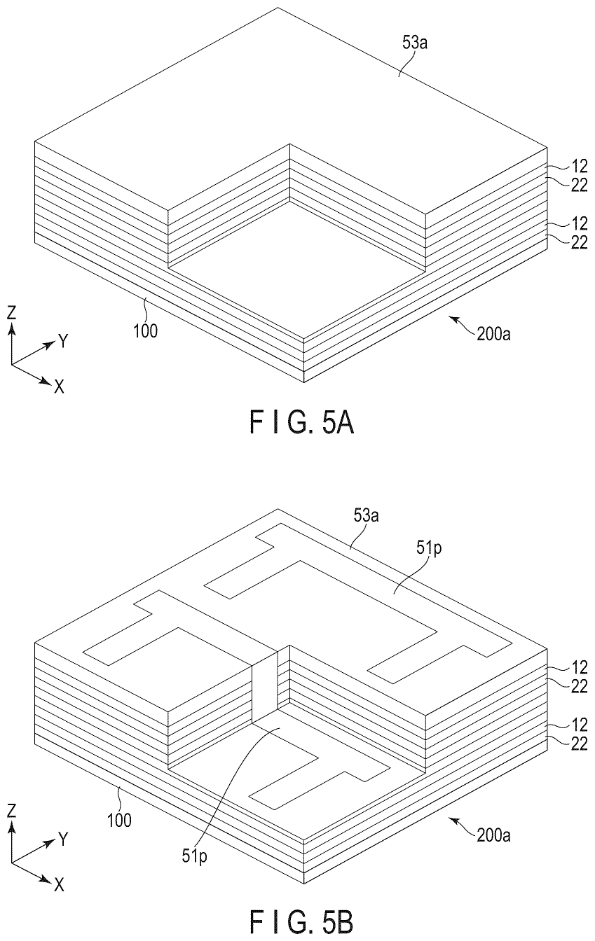

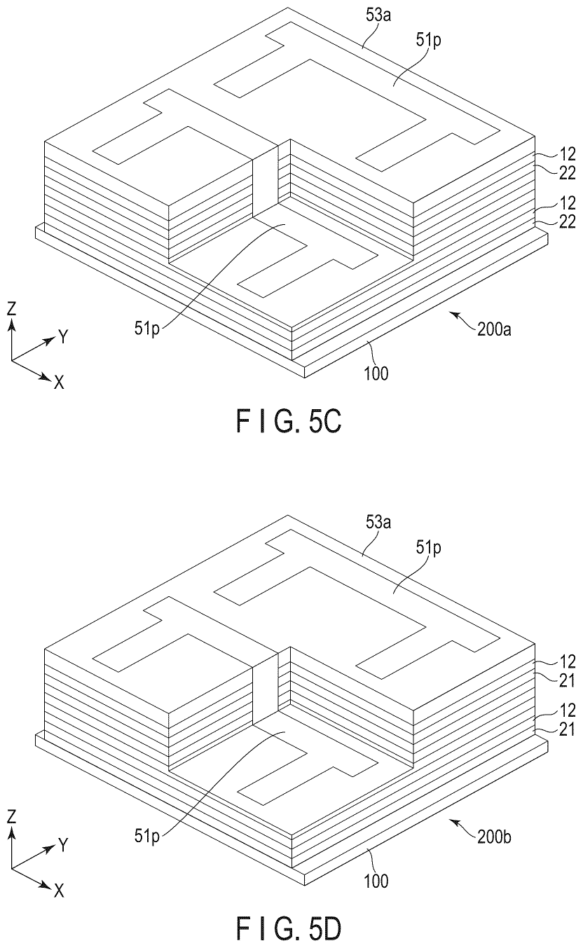

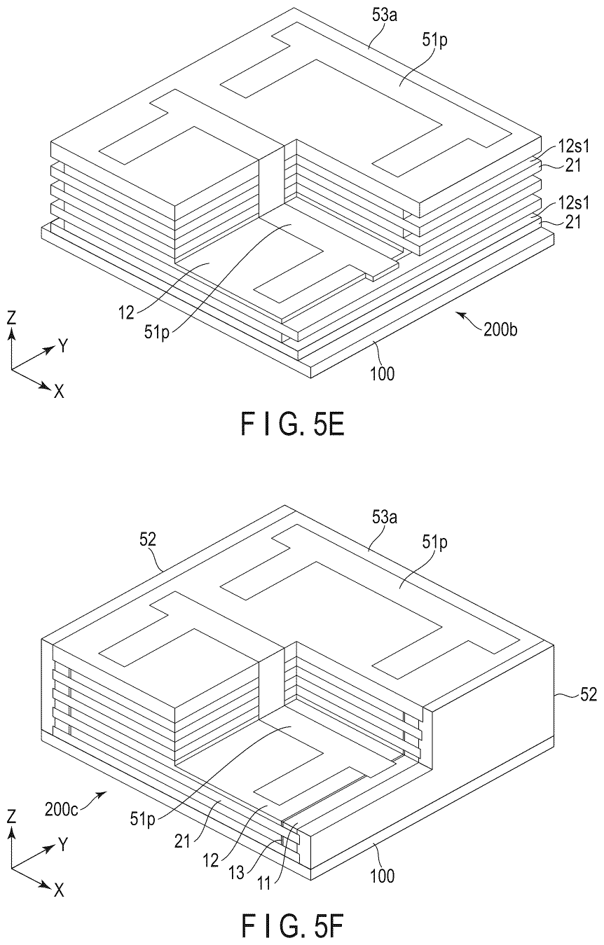

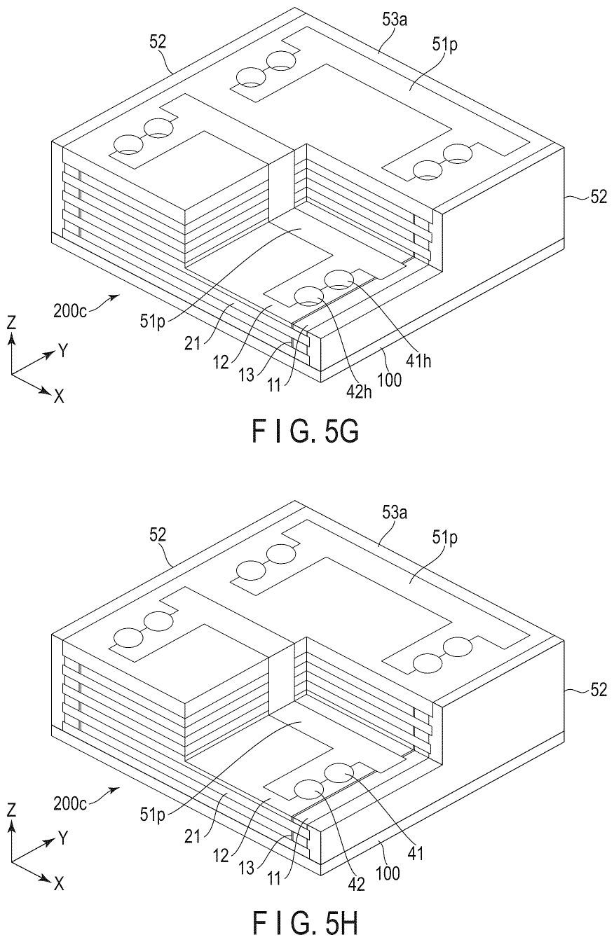

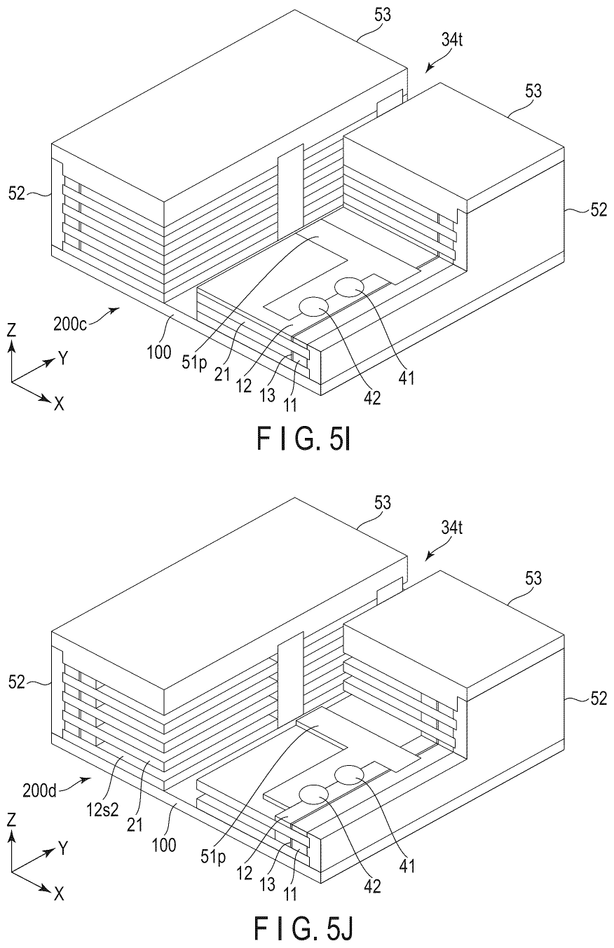

Next, a manufacturing method of a semiconductor memory device according to the present embodiment will be described with reference to FIG. 5A to FIG. 5J. In perspective views illustrated in FIG. 5A to FIG. 5J, a portion on the upper layer side is omitted in one part on the front side of the quadrisected structure similarly to the perspective view illustrated in FIG. 1, however, in an actual device this part is also present and is similar to the other three parts.

First, as illustrated in FIG. 5A, a laminate structure 200a is formed on the semiconductor substrate 100. The laminate structure 200a has a plurality of semiconductor layers 12 and a plurality of sacrificial layers 22 alternately laminated in the Z direction. Silicon (Si) is used for the semiconductor layer 12, and silicon germanium (SiGe) is used for the sacrificial layer 22. Both the semiconductor layer 12 (Si layer) and the sacrificial layer 22 (SiGe layer) have a single crystal (monocrystalline) structure. Subsequently, over the laminate structure 200a, a silicon nitride layer is formed as an upper insulating layer 53a.

Next, as illustrated in FIG. 5B, a groove that reaches the semiconductor substrate 100 is formed in the upper insulating layer 53a and the laminate structure 200a, and this groove is then filled with an insulating material (e.g., silicon oxide). Thus, an insulating part 51p is formed.

Next, as illustrated in FIG. 5C, a portion of the upper insulating layer 53a and a portion of the laminate structure 200a are removed to form a groove for the insulating part 52.

Next, as illustrated in FIG. 5D, the sacrificial layers 22 (SiGe layers) are replaced with the insulating layers 21 (silicon oxide layers). Specifically, a plurality of spaces are formed by etching out the plurality of sacrificial layers 22 (SiGe layers) via the groove formed in the processing of FIG. 5C, and the insulating layers 21 (silicon oxide layers) are formed by filling the plurality of spaces with silicon oxide. Thus, a laminate structure 200b in which the semiconductor layers 12 and the insulating layers 21 are alternately laminated in the Z direction is obtained.

Next, as illustrated in FIG. 5E, a portion of each of the plurality of semiconductor layers 12 (Si layers) is removed and a plurality of spaces 12s1 are thus formed.

Next, as illustrated in FIG. 5F, by oxidizing the plurality of semiconductor layers 12 (Si layers) via the plurality of spaces 12s1 formed in the process of FIG. 5E, the plurality of gate insulating layers 13 (silicon oxide layers) are formed. After forming the gate insulating layers 13, the plurality of word lines 11 are formed by filling the spaces 12s1 with a metal material such as tungsten (W). Further, by filling the groove formed in the process of FIG. 5C with an insulating material such as silicon oxide, the insulating part 52 is formed. In this way, a laminate structure 200c is obtained.

Subsequently, as illustrated in FIG. 5G, a hole 41h for the bit line 41 and a hole 42h for the body contact 42 are formed, and an upper surface of the semiconductor substrate 100 is exposed in these holes.

Next, as illustrated in FIG. 5H, the surface area of the semiconductor substrate 100 at a bottom part of the hole 41h and the surface area of the semiconductor substrate 100 at a bottom part of the hole 42h are doped with an impurity element respectively and separately. Further, by filling the hole 41h and the hole 42h with a metal material such as tungsten (W), the bit line 41 and the body contact 42 are formed.

Next, as illustrated in FIG. 5I, by forming a silicon nitride layer on the structure obtained in the process in FIG. 5H, the upper insulating layer 53 is obtained. Then, a groove 34t for the common electrode 34 is formed passing through the upper insulating layer 53, the laminate structure 200c, and the insulating part 51p, and the surface of the semiconductor substrate 100 is exposed.

Subsequently, as illustrated in FIG. 5J, a portion of each of the plurality of semiconductor layers 12 is etched via the groove 34t, and a plurality of spaces 12s2 are thus formed.

Thereafter, as illustrated in FIG. 1, FIG. 2, and FIG. 3, the plurality of capacitors 30 and the common electrode 34 are formed inside the plurality of spaces 12s2 and inside the groove 34t or the like. Specifically, the plurality of capacitor electrodes 31 are first formed inside the plurality of spaces 12s2. Next, a plurality of spaces are formed by etching the insulating layers 21. The insulating part 51p is also etched and a groove is formed. Further, inside the plurality of spaces and inside the groove obtained in this way, the capacitor dielectric layer 33 and the capacitor electrode 32 are formed. When forming the capacitor electrode 32, the common electrode 34 is formed inside the groove 34t.

As above, the semiconductor memory device having the structure as illustrated in FIG. 1, FIG. 2, FIG. 3, and FIG. 4 is formed.

By the manufacturing method described above, it is possible to accurately form the semiconductor memory device including the plurality of memory cells of a reduced cell size.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device, comprising:
a laminated structure with a plurality of first layers and a plurality of second layers alternately stacked in a first direction;
a first bit line that extends in the first direction through the laminated structure; and
a second bit line that extends in the first direction through the laminated structure, the second bit line being spaced from the first bit line in a second direction crossing the first direction, wherein
each first layer includes:
a word line that extends in the second direction,
a first semiconductor layer that extends in the second direction alongside word line and is connected to the first bit line,
a second semiconductor layer that extends in the second direction alongside the word line, the second semiconductor layer being spaced from the first semiconductor layer in the second direction and connected to the second bit line,
a first gate insulating layer between the word line and the first semiconductor layer,
a second gate insulating layer between the word line and the second semiconductor layer,
a first part of a first capacitor connected to the first semiconductor layer, and
a first part of a second capacitor connected to the second semiconductor layer.

2. The semiconductor memory device of claim 1, wherein the word lines in each first layer overlap when viewed from the first direction.

3. The semiconductor memory device of claim 1, wherein
the first semiconductor layers overlap with each other when viewed from the first direction, and
the second semiconductor layers overlap with each other when viewed from the first direction.

4. The semiconductor memory device of claim 1, wherein, when viewed from the first direction, the first semiconductor layers are aligned with the second semiconductor layers on a straight line that extends in the second direction.

5. The semiconductor memory device of claim 1, further comprising:
a first body contact that extends in the first direction through the laminated structure, the first body contact being connected to the first semiconductor layers; and
a second body contact that extends in the first direction through the laminated structure, the second body contact being connected to the second semiconductor layers.

6. The semiconductor memory device of claim 5, wherein the first bit line, the second bit line, the first body contact, and the second body contact are formed of the same conductive material.

7. The semiconductor memory device of claim 1, wherein each second layer includes:
an insulating layer which has a part between word lines adjacent to each other in the first direction, a part between first semiconductor layers adjacent to each other in the first direction, and a part between second semiconductor layers adjacent to each other in the first direction.

8. The semiconductor memory device of claim 1, wherein
each first capacitor further includes a second part in an adjacent second layer, and
each second capacitor further includes a second part, provided in the adjacent second layer.

9. The semiconductor memory device of claim 1, wherein each first capacitor and each second capacitor includes a first electrode, a second electrode, and a dielectric layer provided between the first electrode and the second electrode.

10. The semiconductor memory device of claim 9, wherein
the first electrode of each first capacitor is connected to a corresponding first semiconductor layer, and
the first electrode of each second capacitor is connected to a corresponding second semiconductor layer.

11. The semiconductor memory device of claim 9, further comprising:
a common electrode that extends in the first direction through the laminated structure, the common electrode being connected to each second electrode of the first and second capacitors.

12. The semiconductor memory device of claim 1, further comprising:
a first insulating part that extends in the first direction through the laminated structure, the first insulating part being between the first semiconductor layers and the second semiconductor layers in the second direction.

13. The semiconductor memory device of claim 12, further comprising:
a second insulating part that extends in the first direction through the laminated structure, the second insulating part being adjacent to the first semiconductor layers in a third direction crossing the first and second directions.

14. The semiconductor memory device of claim 13, wherein the first insulating part and the second insulating part are integrally connected.

15. The semiconductor memory device of claim 13, wherein the first bit line is between the first semiconductor layers and the second insulating part when viewed from the first direction.

16. The semiconductor memory device of claim 13, further comprising:
a third insulating part that extends in the first direction through the laminated structure, the third insulating part being adjacent to the word lines in the third direction.

17. A semiconductor memory device, comprising:
a laminated structure with a plurality of first layers and a plurality of second layers alternately stacked in a first direction;
a common electrode that extends through the laminated structure in the first direction and extends a second direction crossing the first direction to divide the laminated structure into a first side and second side, the common electrode being between the first side and the second side in a third direction crossing the first and second directions;
a first bit line in a first section on the first side of the laminated structure, the first bit line extending in the first direction through the laminated structure; and
a second bit line in a second section on the first side of the laminated structure, the second bit line extending in the first direction through the laminated structure, the second bit line being spaced from the first bit line in the second direction, wherein
each first layer includes:
a word line that extends in the second direction,
a first semiconductor layer that extends in the second direction alongside word line and is connected to the first bit line,
a second semiconductor layer that extends in the second direction alongside the word line, the second semiconductor layer being spaced from the first semiconductor layer in the second direction and connected to the second bit line,
a first gate insulating layer between the word line and the first semiconductor layer,
a second gate insulating layer between the word line and the second semiconductor layer,
a first part of a first capacitor connected to the first semiconductor layer; and
each second layer includes:
an insulating layer which has a part between word lines adjacent to each other in the first direction, a part between first semiconductor layers adjacent to each other in the first direction, and
a second part of the first capacitor that is in an adjacent first layer.

18. The semiconductor memory device of claim 17, further comprising:
a body contact in the first section and extending in the first direction through the laminated structure, the body contact being connected to the first semiconductor layers.

19. The semiconductor memory device of claim 17, wherein the first bit line is a columnar structure.

20. The semiconductor memory device of claim 17, further comprising:
a first insulating part that extends in the first direction through the laminated structure, the first insulating part being between the first semiconductor layers and the second semiconductor layers in the second direction, and
a second insulating part that extends in the first direction through the laminated structure, the second insulating part being adjacent to the first semiconductor layers in the third direction.
